(19) United States
(12) Patent Application Publication
(10) Pub. No.: US 2026/0239536 A1
(43) Pub. Date: Aug. 13, 2026

(54) PRINTED WIRING BOARD

(71) Applicants: SUMITOMO ELECTRIC PRINTED CIRCUITS, INC., Shiga (JP); SUMITOMO ELECTRIC INDUSTRIES, LTD., Osaka (JP)

(72) Inventors: Yukinori NISHIMURA, Shiga (JP); Hiroshi UEDA, Shiga (JP); Shun IGARASHI, Osaka (JP); Ichiro KUWAYAMA, Osaka (JP); Suguru YAMAGISHI, Osaka (JP); Toyohisa TAKANO, Osaka (JP)

(73) Assignees: SUMITOMO ELECTRIC PRINTED CIRCUITS, INC., Shiga (JP); SUMITOMO ELECTRIC INDUSTRIES, LTD., Osaka (JP)

(21) Appl. No.: 19/154,037

(22) PCT Filed: Feb. 6, 2024
(86) PCT No.: PCT/JP2024/003791

§ 371 Date: Aug. 6, 2025

(30) Foreign Application Priority Data
Feb. 8, 2023 (JP) 2023-017722

(51) Int. Cl. H05K 1/11; H05K 1/02; H05K 3/00; H05K 3/46

(52) U.S. Cl. CPC H05K 1/116; H05K 1/0245; H05K 3/0011; H05K 3/46; H05K 2201/09236; H05K 2201/09454; H05K 2201/09509; H05K 2201/09827

(57) ABSTRACT

This printed wiring board includes a first signal pattern, a second signal pattern, at least one dielectric layer disposed therebetween, and a conductor layer. The first and second signal patterns have a strip shape in plan view and have a first end and a second end, respectively. The first signal pattern has a first land at the first end, the second signal pattern has a second land at the second end, at least part of the first land overlaps the second land in plan view, the at least one dielectric layer has a through-hole formed therein, the conductor layer is embedded in the through-hole and electrically connects the first land to the second land, and a distance between an opening edge of the through-hole and the first end in plan view is different from a distance between the opening edge of the through-hole and the second end in plan view.

### TECHNICAL FIELD

The present disclosure relates to a printed wiring board. The present application claims priority based on Japanese Patent Application No. 2023-017722 filed on Feb. 8, 2023, and the entire contents of the Japanese patent application are incorporated herein by reference.

### BACKGROUND ART

For example, Japanese Unexamined Patent Application Publication No. 2022-151716 (PTL 1) describes a printed wiring board. The printed wiring board described in PTL 1 includes a first dielectric layer, a first signal pattern disposed on the first dielectric layer, and a second dielectric layer disposed on the first dielectric layer so as to cover the first signal pattern.

### CITATION LIST

### Patent Literature

PTL 1: Japanese Unexamined Patent Application Publication No. 2022-151716

### SUMMARY OF INVENTION

A printed wiring board according to the present disclosure includes a first signal pattern, a second signal pattern, at least one dielectric layer disposed between the first signal pattern and the second signal pattern, and a conductor layer. The first signal pattern has a strip shape in plan view and has a first end. The second signal pattern has a strip shape in plan view and has a second end. The first signal pattern has a first land at the first end. The second signal pattern has a second land at the second end. At least part of the first land overlaps the second land in plan view, and the at least one dielectric layer has a through-hole formed therein. The conductor layer is embedded in the through-hole and electrically connects the first land to the second land. A distance between an opening edge of the through-hole and the first end in plan view is different from a distance between the opening edge of the through-hole and the second end in plan view.

### BRIEF DESCRIPTION OF DRAWINGS

FIG. 1 is a plan view of a printed wiring board 100.

FIG. 2 is a plan view of the printed wiring board 100 in which the illustration of a dielectric layer 30 is omitted.

FIG. 3 is a sectional view taken along III-III in FIG. 1.

FIG. 4 is a plan view of a printed wiring board 100A.

FIG. 5 is a plan view of the printed wiring board 100A in which the illustration of a dielectric layer 30 is omitted.

FIG. 6 is a sectional view of a printed wiring board 100B.

FIG. 7 is a sectional view of a printed wiring board 100C.

FIG. 8 is a sectional view of a printed wiring board 100D.

FIG. 9 is a flowchart illustrating a manufacturing process of the printed wiring board 100.

FIG. 10 is a sectional view illustrating a first patterning step S2.

FIG. 11 is a sectional view illustrating a dielectric layer attaching step S3.

FIG. 12 is a sectional view illustrating a through-hole forming step S4.

FIG. 13 is a sectional view illustrating a conductor layer forming step S5.

FIG. 14 illustrates simulation results of reflection coefficients of Sample 1 and Sample 2.

FIG. 15 illustrates simulation results of reflection coefficients of Sample 3 and Sample 4.

FIG. 16 illustrates simulation results of reflection coefficients of Sample 5 and Sample 6.

FIG. 17 illustrates simulation results of reflection coefficients of Sample 7 and Sample 8.

### DETAILED DESCRIPTION

### Problems to be Solved by Present Disclosure

In the printed wiring board described in PTL 1, a signal pattern (second signal pattern) different from the first signal pattern may be disposed on the second dielectric layer for the purpose of electrical connection to the outside. In this case, an end portion of the first signal pattern and an end portion of the second signal pattern serve as a first land and a second land, respectively. The first land and the second land overlap each other in plan view. In this case, a through-hole through which the first land is exposed is formed in the second land and the second dielectric layer, and a conductor layer is embedded in the through-hole to electrically connect the first land and the second land to each other. The connection structure described above becomes a reflection point of a high-frequency signal flowing through the first signal pattern and the second signal pattern, and causes degradation of high-frequency characteristics.

The present disclosure has been made in view of the above problem in the related art. More specifically, the present disclosure provides a printed wiring board capable of improving high-frequency characteristics.

### Advantageous Effects of Present Disclosure

According to the printed wiring board according to the present disclosure, high-frequency characteristics can be improved.

### Description of Embodiments of Present Disclosure

First, embodiments of the present disclosure will be listed and described.

(1) A printed wiring board according to an embodiment includes a first signal pattern, a second signal pattern, at least one dielectric layer disposed between the first signal pattern and the second signal pattern, and a conductor layer. The first signal pattern has a strip shape in plan view and has a first end. The second signal pattern has a strip shape in plan view and has a second end. The first signal pattern has a first land at the first end. The second signal pattern has a second land at the second end. At least part of the first land overlaps the second land in plan view. The at least one dielectric layer has a through-hole formed therein. The conductor layer is embedded in the through-hole and electrically connects the first land to the second land. A distance between an opening edge of the through-hole and the first end in plan view is different from a distance between the opening edge of the through-hole and the second end in plan view. According to the printed wiring board of (1) above, high-frequency characteristics can be improved.

(2) The printed wiring board of (1) above may include a first dielectric layer and a second dielectric layer serving as the at least one dielectric. The first signal pattern may be disposed on the first dielectric layer. The second dielectric layer may be disposed on the first dielectric layer so as to cover the first signal pattern. The second signal pattern is disposed on the second dielectric layer. The through-hole may be formed in the second dielectric layer.

(3) In the printed wiring board of (1) or (2) above, an outer diameter of the first land may be different from an outer diameter of the second land. According to the printed wiring board of (2) above, high-frequency characteristics can be further improved.

(4) In the printed wiring board of any one of (1) to (3) above, in plan view, a width of the first signal pattern in a direction orthogonal to a direction in which the first signal pattern extends may be different from a width of the second signal pattern in a direction orthogonal to a direction in which the second signal pattern extends in plan view.

(5) In the printed wiring board of any one of (2) to (4) above, a thickness of the first dielectric layer may be different from a thickness of the second dielectric layer. According to the printed wiring board of (4) above, high-frequency characteristics can be further improved.

(6) In the printed wiring board of any one of (2) to (4) above, a thickness of the first dielectric layer may be equal to a thickness of the second dielectric layer.

(7) In the printed wiring board of (3) above, the outer diameter of the first land may be smaller than the outer diameter of the second land.

(8) In the printed wiring board of (4) above, in plan view, the width of the first signal pattern in the direction orthogonal to the direction in which the first signal pattern extends may be smaller than the width of the second signal pattern in the direction orthogonal to the direction in which the second signal pattern extends.

(9) In the printed wiring board of (7) or (8) above, in plan view, a center of the first land, a center of the second land, and a center of the through-hole may coincide with each other.

### Details of Embodiments of Present Disclosure

Details of embodiments of the present disclosure will be described with reference to the drawings. In the drawings, the same or equivalent parts are assigned the same reference signs, and are not described repeatedly. A printed wiring board according to an embodiment is referred to as a printed wiring board 100.

### (Configuration of Printed Wiring Board 100)

The configuration of a printed wiring board 100 will be described below.

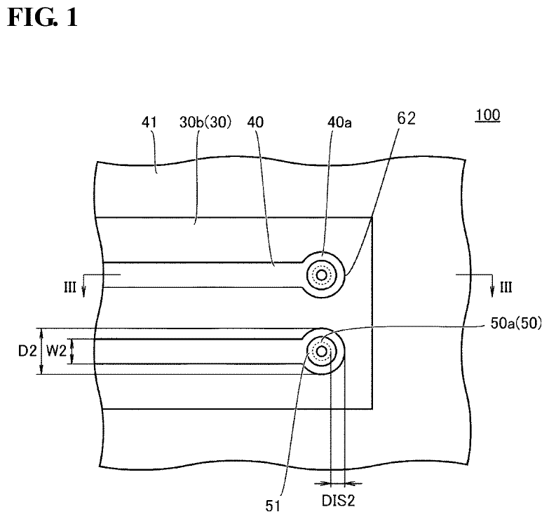

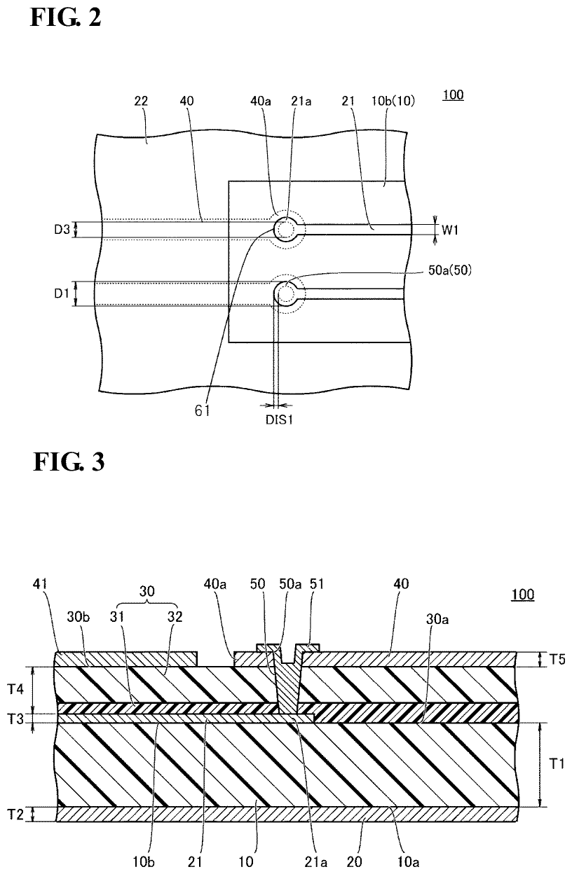

FIG. 1 is a plan view of the printed wiring board 100. FIG. 2 is a plan view of the printed wiring board 100 in which the illustration of a dielectric layer 30 is omitted. The dielectric layer 30 may be referred to as a second dielectric layer. FIG. 3 is a sectional view taken along III-III in FIG. 1. As illustrated in FIG. 1 to FIG. 3, the printed wiring board 100 includes a dielectric layer 10, a ground pattern 20, a signal pattern 21, a ground pattern 22, a dielectric layer 30, a signal pattern 40, a ground pattern 41, and a conductor layer 51. The dielectric layer 10 may be referred to as a first dielectric layer. The signal pattern 21 and the signal pattern 40 may be referred to as a first signal pattern and a second signal pattern, respectively.

The constituent material of the dielectric layer 10 is a dielectric. A specific example of the constituent material of the dielectric layer 10 is, for example, a fluororesin. However, the constituent material of the dielectric layer 10 is not limited thereto. The dielectric layer 10 has a main surface 10a and a main surface 10b. The main surface 10a and the main surface 10b are end surfaces of the dielectric layer 10 in the thickness direction. The thickness of the dielectric layer 10 is defined as a thickness T1.

The ground pattern 20 is disposed on the main surface 10a. The constituent material of the ground pattern 20 is, for example, copper. A ground potential is applied to the ground pattern 20. The thickness of the ground pattern 20 is defined as a thickness T2.

The signal pattern 21 is disposed on the main surface 10b. In plan view of the printed wiring board 100, the signal pattern 21 includes a first end 61 at a leading end in a direction in which the signal pattern 21 extends. The signal pattern 21 has a strip shape in plan view. The direction in which the signal pattern 21 extends in plan view of the printed wiring board 100 is defined as a first direction. A high-frequency signal flows through the signal pattern 21. In the example illustrated in FIG. 1 to FIG. 3, the number of signal patterns 21 is 2. The two signal patterns 21 are arranged in a second direction with a gap therebetween. The second direction is a direction orthogonal to the first direction in plan view. The two signal patterns 21 form differential signal lines. The number of signal patterns 21 may be 1. That is, the signal pattern 21 may form a single-ended signal line. The constituent material of the signal pattern 21 is, for example, copper. The signal pattern 21 has a land 21a at the first end 61. The land 21a has, for example, a partial-circle shape in plan view. The partial-circle shape refers to a shape in which a portion of the arc of a circle is replaced by the chord.

An outer diameter D1 of the land 21a is larger than or equal to a width W1 of the signal pattern 21 in the second direction.

The ground pattern 22 is disposed on the main surface 10b. The constituent material of the ground pattern 22 is, for example, copper. The ground pattern 22 is set to have the ground potential. The ground pattern 22 surrounds the signal pattern 21 in plan view. The thickness of the signal pattern 21 and the thickness of the ground pattern 22 are each defined as a thickness T3.

The dielectric layer 30 is disposed on the main surface 10b so as to cover the signal pattern 21 and the ground pattern 22. The dielectric layer 30 has a main surface 30a and a main surface 30b. The main surface 30a and the main surface 30b are end surfaces of the dielectric layer 30 in the thickness direction. The main surface 30a faces the dielectric layer 10. The main surface 30b is a surface opposite to the main surface 30b.

The dielectric layer 30 includes a first layer 31 and a second layer 32. The first layer 31 and the second layer 32 form the main surface 30a and the main surface 30b, respectively. The second layer 32 is disposed on the first layer 31. The constituent material of the dielectric layer 30 is a dielectric. The constituent material of the first layer 31 is, for example, an adhesive. The constituent material of the second layer 32 is, for example, a fluororesin. However, the constituent materials of the first layer 31 and the second layer 32 are not limited thereto. The constituent material of the first layer 31 may be the same as the constituent material of the second layer 32. The thickness of the dielectric layer 30 is defined as a thickness T4. The thickness T4 may be equal to or larger than the thickness T1. The thickness T4 may be smaller than the thickness T1. The thickness T4 and the thickness T1 may be equal to or different from each other.

The signal pattern 40 is disposed on the main surface 30b. That is, one dielectric layer (dielectric layer 30) is disposed between the signal pattern 21 and the signal pattern 40. The signal pattern 40 has a strip shape in plan view. In plan view, the signal pattern 40 includes a second end 62 at a leading end in a direction in which the signal pattern 40 extends. The signal pattern 40 extends from the second end 62 in the first direction in plan view. A high-frequency signal flows through the signal pattern 40. In the example illustrated in FIG. 1 to FIG. 3, the number of signal patterns 40 is 2. The two signal patterns 40 are arranged in the second direction with a gap therebetween. That is, the two signal patterns 40 form differential signal lines. The number of signal patterns 40 may be 1. That is, the signal pattern 40 may form a single-ended signal line. The constituent material of the signal pattern 40 is, for example, copper. The signal pattern 40 has a land 40a at the second end 62. At least part of the land 21a overlaps the land 40a in plan view. The land 40a has, for example, a partial-circle shape in plan view.

A width W2 of the signal pattern 40 in the second direction may be different from the width W1. The width W2 is, for example, larger than the width W1. An outer diameter D2 of the land 40a is, for example, equal to the width W2 or larger than the width W2. The outer diameter D2 may be different from the outer diameter D1. The outer diameter D2 is, for example, larger than the outer diameter D1. The constituent material of the signal pattern 40 is, for example, copper.

The ground pattern 41 is disposed on the main surface 30b. The constituent material of the ground pattern 41 is, for example, copper. The ground pattern 41 is set to have the ground potential. The ground pattern 41 surrounds the signal pattern 40 in plan view. The thickness of the signal pattern 40 and the thickness of the ground pattern 41 are each defined as a thickness T5.

A through-hole 50 extending through the dielectric layer 30 and the land 40a is formed. The land 21a is exposed from the bottom of the through-hole 50. The conductor layer 51 is embedded in the through-hole 50. More specifically, the conductor layer 51 is disposed on the inner wall surface of the through-hole 50, on the land 21a exposed from the bottom of the through-hole 50, and on the land 40a located around the through-hole 50. The conductor layer 51 electrically connects the land 21a to the land 40a. The opening diameter of the through-hole 50 may be tapered from the land 40a toward the land 21a. The opening edge at the upper end of the through-hole 50 is defined as an opening edge 50a. The opening diameter of the opening edge 50a is defined as an opening diameter D3.

The distance between the first end 61 of the signal pattern 21 and the opening edge 50a in plan view is defined as a distance DIS1, and the distance between the second end 62 of the signal pattern 40 and the opening edge 50a in plan view is defined as a distance DIS2. As described above, the outer diameter D1 and the outer diameter D2 are different from each other. The distance DIS1 and the distance DIS2 are different from each other. The distance DIS2 is, for example, larger than the distance DIS1.

### Modifications

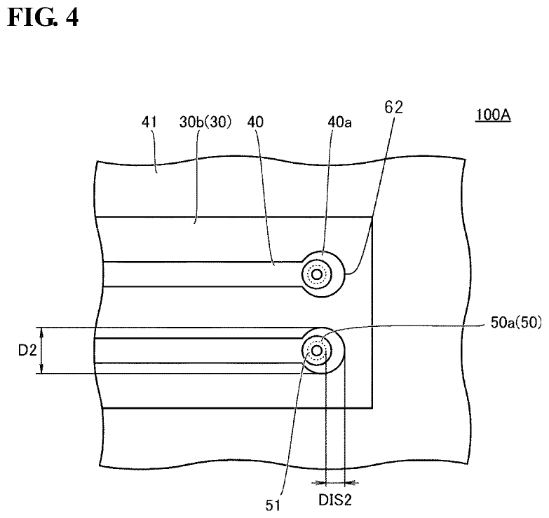

FIG. 4 is a plan view of a printed wiring board 100A. FIG. 5 is a plan view of the printed wiring board 100A in which the illustration of a dielectric layer 30 is omitted. As illustrated in FIG. 4 and FIG. 5, the outer diameter D1 and the outer diameter D2 may be equal to each other. In this case, since the center of a through-hole 50 is shifted from the center of a land 21a and the center of a land 40a in plan view, the distance DIS1 and the distance DIS2 are different from each other. The through-hole 50 has, for example, a circular shape in plan view. The shape of each of the land 21a and the land 40a is, for example, a partial-circle shape.

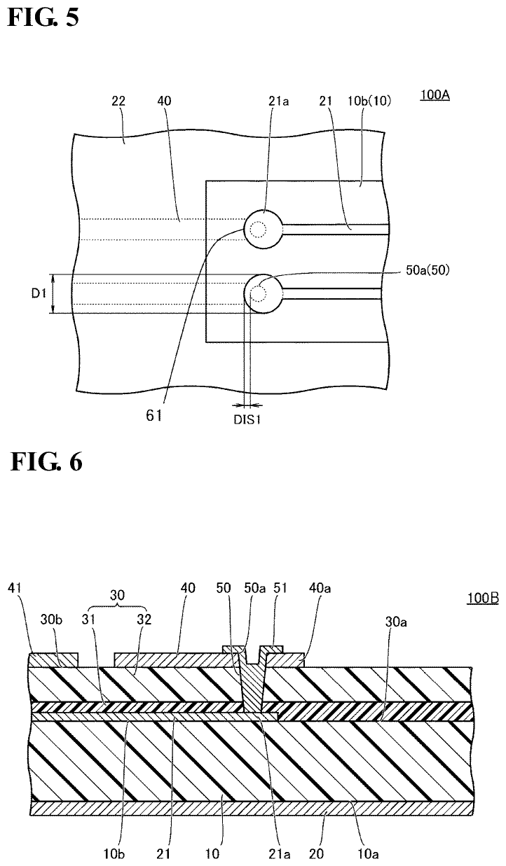

FIG. 6 is a sectional view of a printed wiring board 100B. As illustrated in FIG. 6, in the printed wiring board 100B, a signal pattern 40 extends from a land 40a in a direction opposite to the first direction. That is, it is only necessary that the signal pattern 40 extend in a direction parallel to the first direction (a direction in which a signal pattern 21 extends or a direction opposite to the signal pattern 21). Alternatively, the signal pattern 40 may extend in a direction that is not parallel to the first direction.

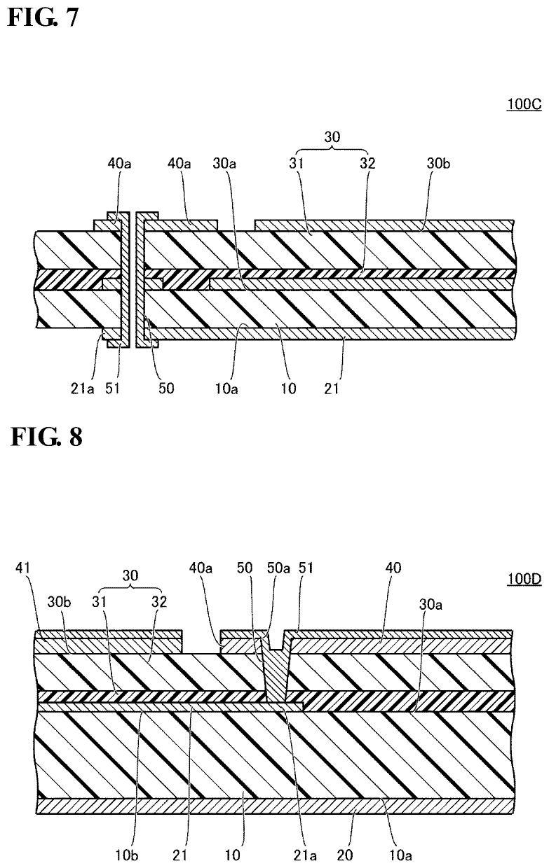

FIG. 7 is a sectional view of a printed wiring board 100C. As illustrated in FIG. 7, in the printed wiring board 100C, a signal pattern 21 is disposed on a main surface 10b. In the printed wiring board 100C, a through-hole 50 extends through a land 21a, a dielectric layer 10, a dielectric layer 30, and a land 40a. That is, a plurality of dielectric layers (dielectric layer 10 and dielectric layer 30) may be disposed between the signal pattern 21 and a signal pattern 40. It is only necessary that the through-hole 50 be formed so as to extend through the plurality of dielectric layers and that a conductor layer 51 be embedded in the through-hole 50 and electrically connect the land 21a to the land 40a.

FIG. 8 is a sectional view of a printed wiring board 100D. As illustrated in FIG. 8, a conductor layer 51 may be disposed on a signal pattern 40 and a ground pattern 41. That is, in a conductor layer forming step S5 described later, panel plating may be performed.

### (Method of Manufacturing Printed Wiring Board 100)

A method of manufacturing the printed wiring board 100 will be described below.

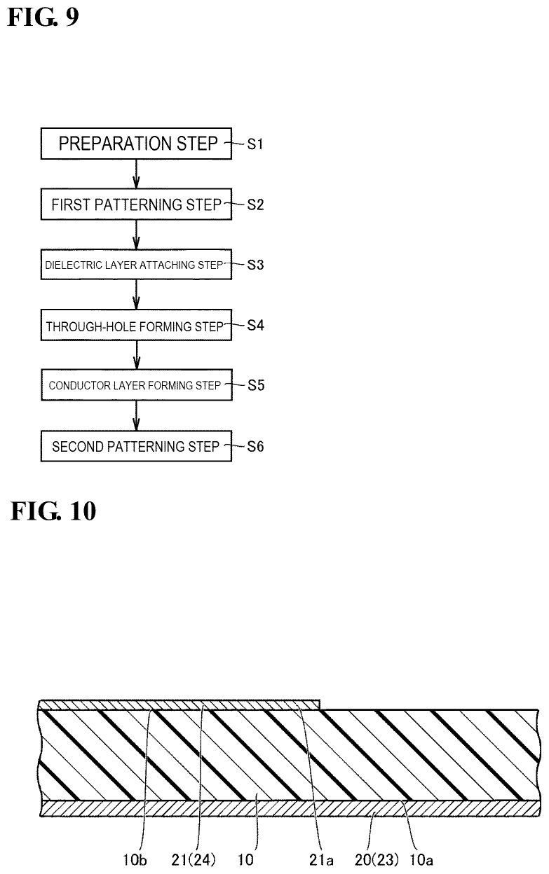

FIG. 9 is a flowchart illustrating a manufacturing process of the printed wiring board 100. As illustrated in FIG. 9, the method of manufacturing the printed wiring board 100 includes a preparation step S1, a first patterning step S2, a dielectric layer attaching step S3, a through-hole forming step S4, a conductor layer forming step S5, and a second patterning step S6.

In the preparation step S1, a dielectric layer 10 is prepared. A copper layer 23 and a copper layer 24 are disposed on a main surface 10a and a main surface 10b, respectively, of the dielectric layer 10 prepared in the preparation step S1. After the preparation step S1, the first patterning step S2 is performed.

FIG. 10 is a sectional view illustrating the first patterning step S2. As illustrated in FIG. 10, in the first patterning step S2, a signal pattern 21 and a ground pattern 22 are formed by patterning the copper layer 24. The patterning of the copper layer 24 is performed by etching using, as a mask, a resist pattern formed on the copper layer 24. The resist pattern is formed by, for example, applying a dry film resist on the copper layer 24, and exposing and developing the applied dry film resist. Note that since the copper layer 23 is not subjected to patterning, the copper layer 23 serves as a ground pattern 20 as it is. After the first patterning step S2, the dielectric layer attaching step S3 is performed.

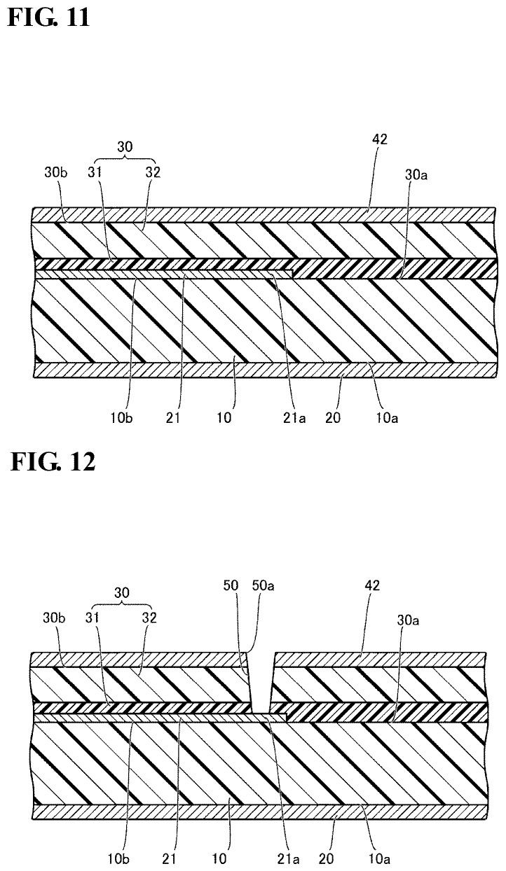

FIG. 11 is a sectional view illustrating the dielectric layer attaching step S3. As illustrated in FIG. 11, in the dielectric layer attaching step S3, a dielectric layer 30 is attached to the main surface 10b so as to cover the signal pattern 21 and the ground pattern 22. In the dielectric layer attaching step S3, first, the dielectric layer 30 is prepared. In the dielectric layer 30 prepared in the dielectric layer attaching step S3, a copper layer 42 is disposed on a main surface 30b, and an adhesive constituting a first layer 31 is in an uncured state.

Secondly, the dielectric layer 30 is disposed on the main surface 10b such that the uncured first layer 31 covers the signal pattern 21 and the ground pattern 22. Thirdly, the dielectric layer 30 is pressed against the dielectric layer 10 while being heated, thereby pressure-bonding the dielectric layer 30 to the dielectric layer 10 with the first layer 31. Thus, the dielectric layer 30 is attached to the dielectric layer 10. After the dielectric layer attaching step S3, the through-hole forming step S4 is performed.

FIG. 12 is a sectional view illustrating the through-hole forming step S4. As illustrated in FIG. 9, in the through-hole forming step S4, a through-hole 50 is formed in the dielectric layer 30 and a portion of the copper layer 42 that will serve as a land 40a after the second patterning step S6. The through-hole 50 is formed by, for example, drilling or laser beam machining. After the through-hole forming step S4, the conductor layer forming step S5 is performed.

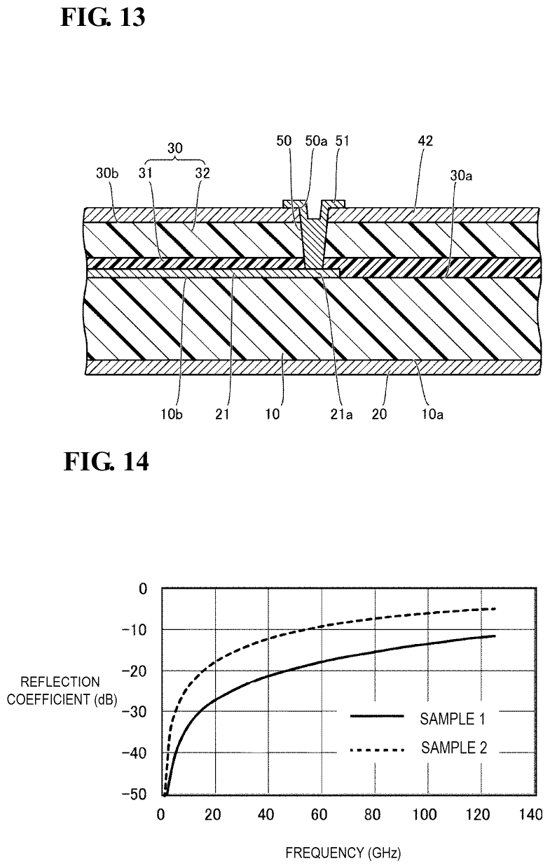

FIG. 13 is a sectional view illustrating the conductor layer forming step S5. As illustrated in FIG. 13, in the conductor layer forming step S5, a conductor layer 51 is formed on the inner wall surface of the through-hole 50, on the copper layer 42 located around the through-hole 50, and on a land 21a exposed from the bottom of the through-hole 50. The conductor layer 51 is formed by, for example, electroless plating and electrolytic plating. After the conductor layer forming step S5, the second patterning step S6 is performed.

In the second patterning step S6, a signal pattern 40 and a ground pattern 41 are formed by pattering the copper layer 24. The patterning of the copper layer 42 is performed by etching using, as a mask, a resist pattern formed on the copper layer 42. The resist pattern is formed by, for example, applying a dry film resist on the copper layer 42, and exposing and developing the applied dry film resist. Thus, the printed wiring board 100 having the structure illustrated in FIG. 1 to FIG. 3 is formed.

### (Advantageous Effects of Printed Wiring Board 100)

Advantageous effects of the printed wiring board 100 will be described below.

As shown in Table 1, Sample 1 to Sample 8 were prepared. In Sample 2, the distance DIS1 and the distance DIS2 are equal to each other (the outer diameter D1 and the outer diameter D2 are equal to each other). On the other hand, in Sample 1, the distance DIS1 and the distance DIS2 are different from each other (the outer diameter D1 and the outer diameter D2 are different from each other). Other conditions are the same for Sample 1 and Sample 2. Similarly, whereas, in Sample 4, the distance DIS1 and the distance DIS2 are equal to each other, in Sample 3, the distance DIS1 and the distance DIS2 are different from each other. Other conditions are the same for Sample 1 and Sample 2.

In Sample 5 and Sample 6, the distance DIS1 and the distance DIS2 are different from each other. However, in Sample 5, the difference between the distance DIS2 and the distance DIS1 is larger than that in Sample 6. In Sample 7 and Sample 8, the distance DIS1 and the distance DIS2 are different from each other. However, in Sample 7, the difference between the distance DIS2 and the distance DIS1 is larger than that in Sample 8.

In Sample 1 to Sample 8, the thickness T2, the thickness T3, and the thickness T5 are 31 μm, 11 μm, and 31 μm, respectively, although not shown in Table 1. In Sample 1 to Sample 8, the center of the land 21a, the center of the land 40a, and the center of the through-hole 50 coincide with each other in plan view. Accordingly, in Sample 1 to Sample 8, distance DIS1=(outer diameter D1−opening diameter D3)/2, and distance DIS2=(outer diameter D2−opening diameter D3)/2.

TABLE 1

| | Outer | Outer | Opening | Thickness | Thickness | Width | Width | Distance | Distance |
|---|---|---|---|---|---|---|---|---|---|
| | diameter D1 | diameter D2 | diameter D3 | T1 | T4 | W1 | W2 | DIS1 | DIS2 |
| Sample | (μm) | (μm) | (μm) | (μm) | (μm) | (μm) | (μm) | (μm) | (μm) |
| 1 | 200 | 275 | 200 | 57 | 133 | 128 | 275 | 0 | 37.5 |
| 2 | 310 | 310 | 200 | 57 | 133 | 128 | 275 | 55 | 55 |
| 3 | 200 | 275 | 200 | 113 | 133 | 190 | 275 | 0 | 37.5 |
| 4 | 310 | 310 | 200 | 113 | 133 | 190 | 275 | 55 | 55 |
| 5 | 150 | 275 | 150 | 57 | 133 | 128 | 275 | 0 | 62.5 |
| 6 | 230 | 275 | 150 | 57 | 133 | 128 | 275 | 40 | 62.5 |
| 7 | 190 | 275 | 150 | 113 | 133 | 190 | 275 | 20 | 62.5 |
| 8 | 230 | 275 | 150 | 113 | 133 | 190 | 275 | 40 | 62.5 |

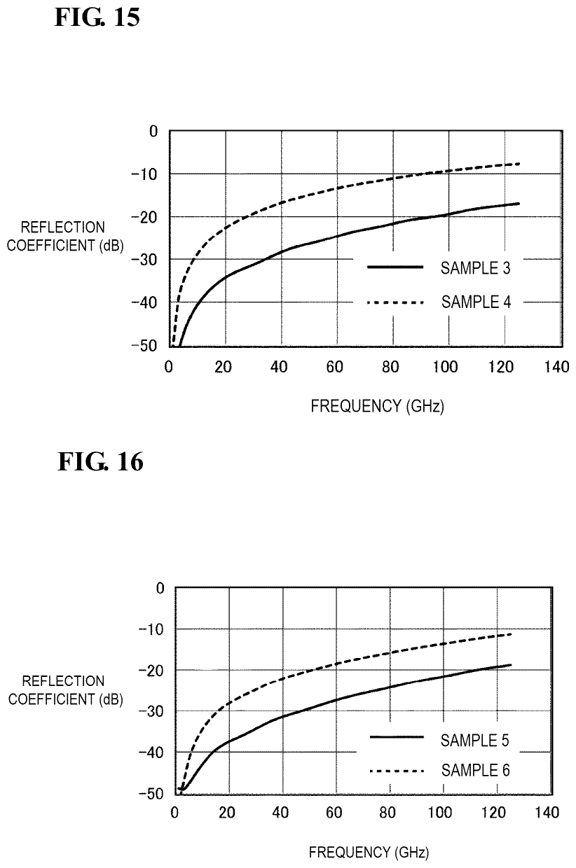

For Sample 1 to Sample 8, reflection coefficients (S11) were calculated by simulation. FIG. 14 illustrates simulation results of the reflection coefficients of Sample 1 and Sample 2. FIG. 15 illustrates simulation results of the reflection coefficients of Sample 3 and Sample 4. In FIG. 14 and FIG. 15, the horizontal axis represents the frequency of a high-frequency signal flowing through the signal pattern 21 and the signal pattern 40, and the vertical axis represents the reflection coefficient. Note that a small value of this vertical axis means that reflection at a connecting portion between the signal pattern 21 and the signal pattern 40 is less likely to occur, and high-frequency characteristics are good.

As shown in FIG. 14 and FIG. 15, in Sample 1, the reflection coefficient was smaller than that in Sample 2, and, in Sample 3, the reflection coefficient was smaller than that in Sample 4. As described above, whereas, in Sample 1 and Sample 3, the distance DIS1 and the distance DIS2 were different from each other, in Sample 2 and Sample 4, the distance DIS1 and the distance DIS2 were equal to each other.

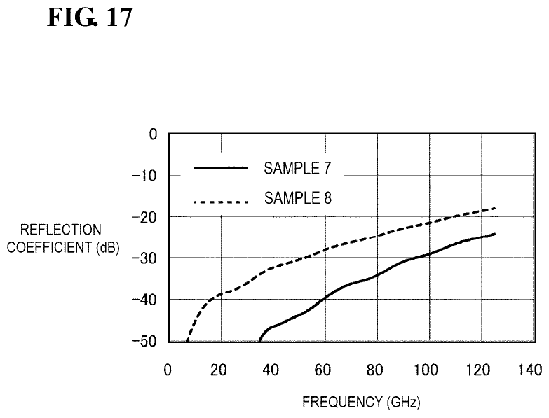

FIG. 16 illustrates simulation results of the reflection coefficients of Sample 5 and Sample 6. FIG. 17 illustrates simulation results of the reflection coefficients of Sample 7 and Sample 8. In FIG. 16 and FIG. 17, the horizontal axis represents the frequency of a high-frequency signal flowing through the signal pattern 21 and the signal pattern 40, and the vertical axis represents the reflection coefficient. As shown in FIG. 16 and FIG. 17, the reflection coefficient of Sample 5 was smaller than the reflection coefficient of Sample 6, and the reflection coefficient of Sample 7 was smaller than the reflection coefficient of Sample 8. As described above, in Sample 5, the difference between the distance DIS2 and the distance DIS1 was larger than that in Sample 6, and, in Sample 7, the difference between the distance DIS2 and the distance DIS1 was larger than that in Sample 8.

These results demonstrated that, in the printed wiring board 100, the occurrence of the reflection of a high-frequency signal at a connecting portion between the signal pattern 21 and the signal pattern 40 was suppressed, and high-frequency characteristics were improved by making the distance DIS2 and the distance DIS1 different from each other.

It is to be understood that the embodiments disclosed herein are only illustrative and non-restrictive in all respects. The scope of the present invention is defined not by the embodiments described above but by the appended claims and is intended to include all modifications that fall within the scope of the claims and the equivalents thereof.

### REFERENCE SIGNS LIST

10 dielectric layer
10a, 10b main surface
20 ground pattern
21 signal pattern
21a land
22 ground pattern
23, 24 copper layer
30 dielectric layer
30a, 30b main surface
31 first layer
32 second layer
40 signal pattern
40a land
41 ground pattern
42 copper layer
50 through-hole
50a opening edge
51 conductor layer
61 first end
62 second end
100, 100A, 100B, 100C, 100D printed wiring board
D1, D2 outer diameter
D3 opening diameter
DIS1, DIS2 distance
S1 preparation step
S2 first patterning step
S3 dielectric layer attaching step
S4 through-hole forming step
S5 conductor layer forming step
S6 second patterning step
T1, T2, T3, T4, T5 thickness
W1, W2 width

1. A printed wiring board comprising:
a first signal pattern;
a second signal pattern;
at least one dielectric layer disposed between the first signal pattern and the second signal pattern; and
a conductor layer,
wherein the first signal pattern has a strip shape in plan view and has a first end,
the second signal pattern has a strip shape in plan view and has a second end,
the first signal pattern has a first land at the first end,
the second signal pattern has a second land at the second end,
at least part of the first land overlaps the second land in plan view, the at least one dielectric layer has a through-hole formed therein,
the conductor layer is embedded in the through-hole and electrically connects the first land to the second land, and
a distance between an opening edge of the through-hole and the first end in plan view is different from a distance between the opening edge of the through-hole and the second end in plan view.

2. The printed wiring board according to claim 1, comprising:
a first dielectric layer; and
a second dielectric layer serving as the at least one dielectric layer,
wherein the first signal pattern is disposed on the first dielectric layer,
the second dielectric layer is disposed on the first dielectric layer so as to cover the first signal pattern,
the second signal pattern is disposed on the second dielectric layer, and
the through-hole is formed in the second dielectric layer.

3. The printed wiring board according to claim 1, wherein an outer diameter of the first land is different from an outer diameter of the second land.

4. The printed wiring board according to claim 1, wherein, in plan view, a width of the first signal pattern in a direction orthogonal to a direction in which the first signal pattern extends is different from a width of the second signal pattern in a direction orthogonal to a direction in which the second signal pattern extends.

5. The printed wiring board according to claim 2, wherein a thickness of the first dielectric layer is different from a thickness of the second dielectric layer.

6. The printed wiring board according to claim 2, wherein a thickness of the first dielectric layer is equal to a thickness of the second dielectric layer.

7. The printed wiring board according to claim 3, wherein the outer diameter of the first land is smaller than the outer diameter of the second land.

8. The printed wiring board according to claim 4, wherein, in plan view, the width of the first signal pattern in the direction orthogonal to the direction in which the first signal pattern extends is smaller than the width of the second signal pattern in the direction orthogonal to the direction in which the second signal pattern extends.

9. The printed wiring board according to claim 7, wherein, in plan view, a center of the first land, a center of the second land, and a center of the through-hole coincide with each other.
